(19) United States
(12) Patent Application Publication
(10) Pub. No.: US 2026/0075725 A1
(43) Pub. Date: Mar. 12, 2026

(54) Portable Router Container or Case Having Integral Power Supply and External Connector Ports

(71) Applicant: Star-Batt LLC, Blanchard, ID (US)

(72) Inventor: Andrew Cole, Blanchard, ID (US)

(73) Assignee: Star-Batt LLC, Blanchard, ID (US)

(21) Appl. No.: 19/204,309

(22) Filed: May 9, 2025

Related U.S. Application Data
(60) Provisional application No. 63/693,649, filed on Sep. 11, 2024.

(51) Int. Cl. H05K 5/00; A45C 13/02; A45C 13/10; H05K 5/02

(52) U.S. Cl. CPC H05K 5/0086; A45C 13/02; A45C 13/1084; H05K 5/0221; A45C 2013/025

(57) ABSTRACT

A case for a router or a signal receiving dish. The case may include a roof portion, a base portion hingedly connected to the roof portion, a latch on an interior of the roof portion, a power supply on an interior of the case, and a port configured to connect to an external power supply. A latch may fixedly secure the dish or router to a roof portion of the case.

### CROSS REFERENCE TO RELATED APPLICATIONS

This application is a non-provisional application of and claims the benefit of and priority to U.S. Provisional Ser. No. 63/693,649 , filed Sep. 11, 2024, the disclosure of which is herein incorporated by reference in its entirety.

### TECHNICAL FIELD OF THE DISCLOSURE

The present disclosure relates, in general, to a protective case or container for housing a satellite receiving dish and/or satellite router, supporting electronics and a rechargeable power supply therefor.

### RELATED ART

This section is intended to provide background information to facilitate a better understanding of various technologies described herein. As the section's title implies, this is a discussion of related art. That such art is related in no way implies that it is prior art. The related art may or may not be prior art. It should therefore be understood that the statements in this section are to be read in this light, and not as admissions of prior art.

Portable internet dish/router cases have previously been designed to protect the physical integrity of remote internet reception devices, i.e., a dish/router (hereinafter collectively referred to as “router”). However, these cases did not include a way to provide power to the router and/or connect the router to an external power source while operating the router while it is secured within the case. This is true regardless of whether the router is a standard sized router, a miniature router, etc.

No one has heretofore created an all-in-one router case with a built in power supply that is resistant to the elements, i.e., waterproof, and that includes an internal hard mount for the router. There has been no user friendly product with all of these features that simplifies how many different products and packages the end user needs in order to power and carry such a remote internet reception device.

Prior art router cases have only held a router inside a case with foam or other packing material, and the router must be removed from the case and powered only when the router is external to the case.

### SUMMARY

Embodiments disclosed herein are directed toward a case, which may include a router or an internet signal receiving dish, a roof portion, and a base portion hingedly connected to the roof portion. A latch mount assembly may be on a first side of an interior surface of the roof portion. The latch mount assembly may be configured to at least partially secure the internet receiving device to the interior surface of the roof. A power supply may be within the case and, at least partially, encompassed by the base portion. One or more ports may be defined in the roof portion and/or base portion. Either, both or all of the ports may be configured to connect to an external power supply. A geometry of the ports may be defined by the base portion of the case. The latch mount assembly may be configured to fixedly secure the dish or router to the roof portion of the case. The internet receiving device is generally a miniature internet receiving device and may be powered by the power supply.

The latch mount assembly may include a rotating latch and a fixed mount. The rotating latch may be configured to rotate relative to the fixed mount. The fixed mount may be on a second side of the interior surface of the roof portion. The second side may oppose the first side. The fixed mount may be configured to at least partially secure the internet receiving device to the roof portion. The latch mount assembly may include at least one second rotating latch. A cross-section of the fixed mount may be substantially C-shaped. The fixed mount may include a receiving slot and adjacent a retaining overhang.

A user interface assembly may be attached to and encompassed by the base portion and may include, the power supply, a positioning surface, a digital display, at least one port coupled to the power supply. The user interface assembly may be configured to supply power from the power supply to an external device and further configured to receive power for recharging the power supply, and may include a controller configured to control operation of the battery, the internet receiving device and the digital display. The positioning surface may be any one or a combination of a bar, a pin, a rail and/or a ridge.

The user interface assembly may be configured to electronically couple to an internet receiving device. The case may include an accessory output port that is configured to relay signals from a satellite to a connected accessory, from a controller within the case to an accessory and from an accessory to electronics within the case.

The above referenced summary section is provided to introduce a selection of concepts in a simplified form that are further described below in the detailed description section. Additional concepts and various other embodiments are also described in the detailed description. The summary is not intended to identify key features or essential features of the claimed subject matter, nor is it intended to be used to limit the scope of the claimed subject matter, nor is it intended to limit the number of inventions described herein. Furthermore, the claimed subject matter is not limited to embodiments that solve any or all disadvantages noted in any part of this disclosure.

### BRIEF DESCRIPTION OF THE DRAWINGS

Embodiments of various techniques will hereafter be described with reference to the accompanying drawings. It should be understood, however, that the accompanying drawings illustrate only the various embodiments described herein and are not meant to limit the scope of various techniques described herein.

FIG. 1 illustrates an embodiment of a case in a closed configuration;

FIG. 2 illustrates the case of FIG. 1 in an opened configuration;

FIG. 3 illustrates a USB port in a lower portion of the case of FIG. 1;

FIG. 4 illustrates a power supply compartment in the case of FIG. 1 and rechargeable batteries residing therein;

FIG. 5 illustrates an upper portion of the case of FIG. 1, revealing rotatable latches on an interior portion thereof;

FIG. 6 illustrates a fixed mount outside of the case of FIG. 1;

FIG. 7 illustrates the lower portion of the case with a user interface assembly therein;

FIG. 8 illustrates a router in process of being inserted into the fixed mount of FIG. 6; and

FIG. 9 the fixed mount bar of FIG. 6, with a router inserted therein.

### DETAILED DESCRIPTION

A compact portable router kit is generally one in which an all-in-one case and battery supply for the router are included in the same assembly. The present disclosure presents an assembly that is configured to allow a miniature router to be powered on without having to remove it from the case, i.e., when the router is internally secured within the case.

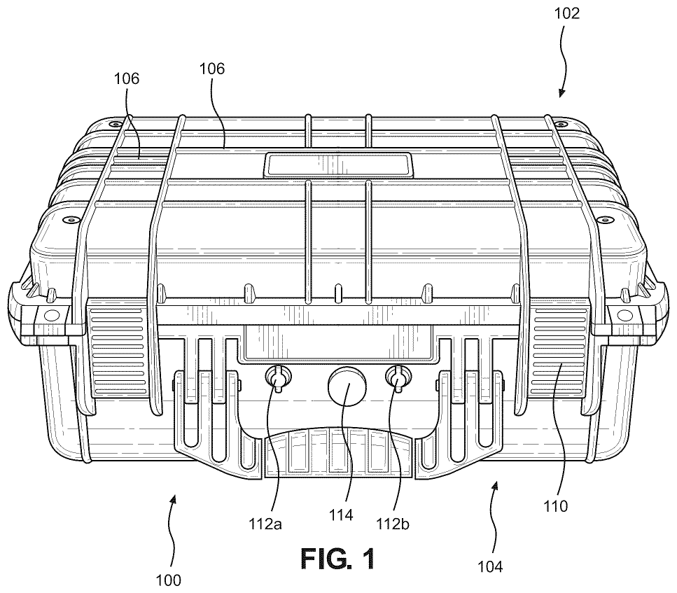

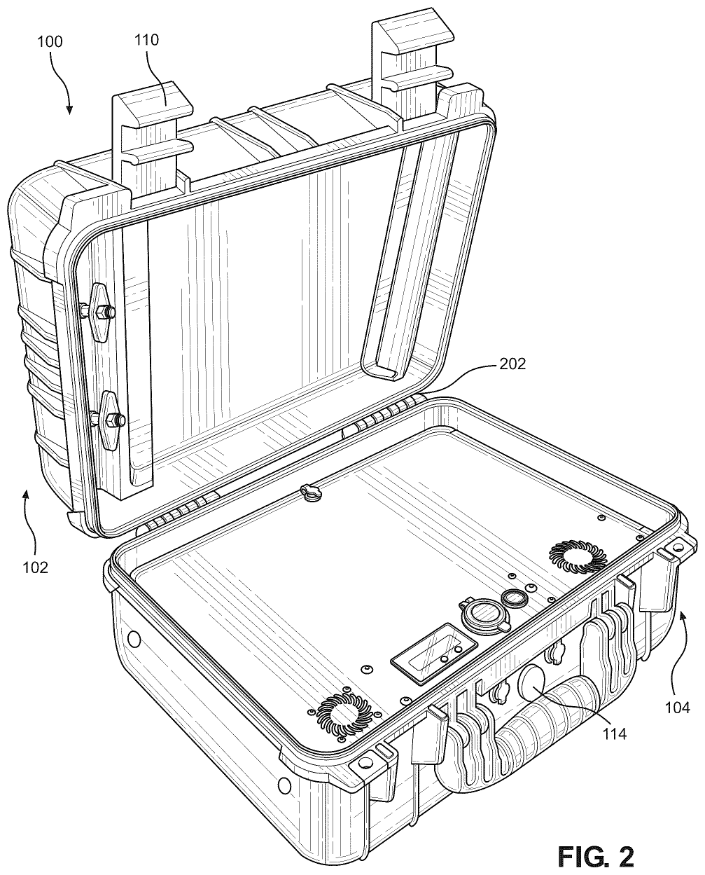

FIGS. 1 and 2 illustrate a case 100 having a roof portion 102 and a base portion 104. The roof portion 102 and the base portion 104 may each define at least one concavity on a respective first side thereof. On a respective second side thereof, there may be a plurality of ribs 106 that define a plurality of second concavities therebetween.

The roof portion 102 and the base portion 104 may be connected to each other by at least one hinge 202 (shown in FIG. 2). It is not necessary that the roof portion 102 be hingedly connected to the base portion 104. The roof portion 102 and the base portion 106 may be similarly sized so that one mates with the other when the case 100 is in a closed configuration.

The roof portion 102 may be locked to the base portion 104 in a closed configuration by a lock or latch mechanism 110. Latch mechanism examples may include a hook latch, a button, a pin, a zipper, a snap and any other mechanism capable of fixedly securing the top portion 102 to the base portion 104.

The case 100 may include various components such as batteries, an on-off switch for supplying electrical power to the router and/or for supplying electrical power to other components within the case. The latch may have a dual function of being a latch for maintenance of the roof portion in physical and locked contact with the base portion and the latch may be an on/off switch for enabling automatic power supply from the batteries to the components within the case when the latch is in a locked or other desirable configuration.

The case 100, when it is in a closed configuration, may be waterproof and thermally insulated. Materials of the roof portion 102 and the base portion 104 may include plastics, metal and fabric. A rubber seal may be provided between the upper portion 102 and the lower portion 104 to promote the watertight character of the case 100.

With further reference to FIGS. 1 and 2, the case 100 may include a power input port 112a, a power output port 112b and a power on/off knob 114. The power input port 112a may be provided to enable charging of a battery within the case 100. The power input port 112a may also be provided to enable electrical operation of the case electronics, with or without simultaneous charging of a battery within the case. Ports 112a and 112b may be separate and independent or they may be combined so that only one port is necessary for both power input and power output operation.

When the output port 112b is used, a satellite router may be coupled thereto and arranged external to the case 100 and used, while still drawing its power from the case's battery. The router may then be moved to an optimum location for view of the sky or to allow the case/battery pack to be placed in a better position for charging, while keeping the dish/router away from the case but still in the best location possible for connection to a satellite network.

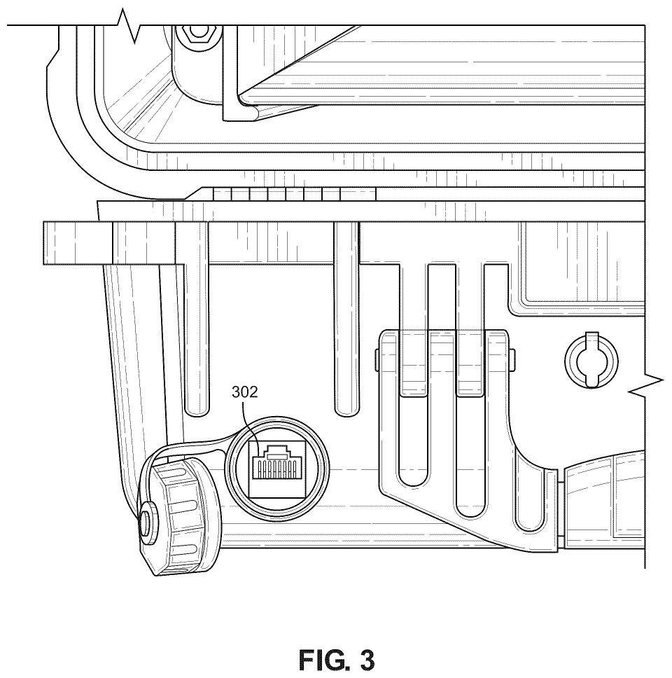

With reference to FIG. 3, an auxiliary port 302 may be provided in the surface of the case. The auxiliary port 302 may be an ethernet port, a USB port, a power port, etc. The auxiliary port 302 may be provided to enable connection of external devices to the case 100 (e.g., phones, laptops, wireless, i.e., LORA, etc., not shown). The auxiliary port 302 may be provided to enable a hardwire ethernet connection between the case 100 and an external device, thereby providing internet access from router within the case 100 to an external device.

The auxiliary port 302 may have an electrical configuration configured to enable control of an external device by a processor within the case 100. Conversely, the auxiliary port 302 may have an electrical configuration configured to enable control by an external device of electronic elements within the case 100. The auxiliary port may be configured to provide power to an external device or to receive power from an external device to charge a battery within the case 100.

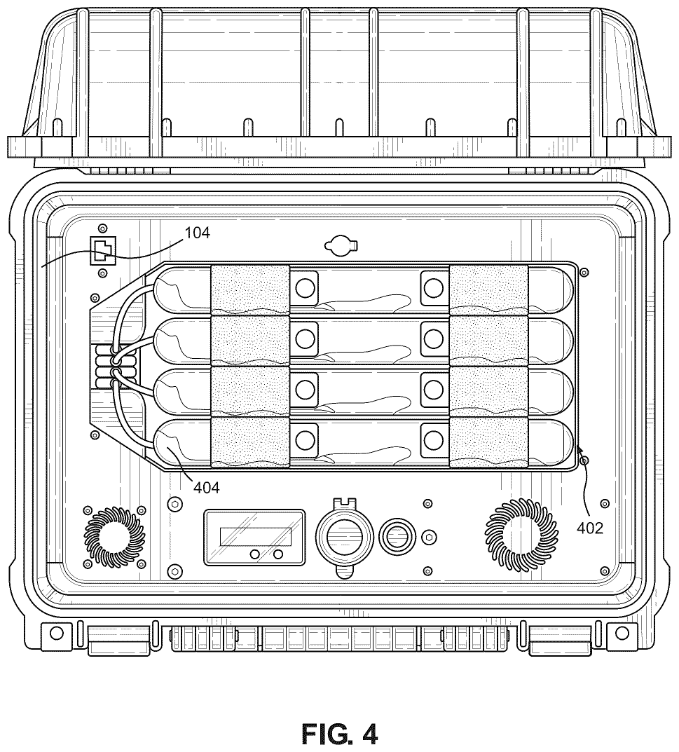

With reference to FIG. 4, the lower portion 104 may include a power supply compartment 402. The power supply compartment 402 may be a receptacle for a battery or plurality of batteries 404. The power supply compartment 402 may be sized and shaped to correspond to the size and shape of a battery and electrical contacts/wires so that a battery or plurality of batteries fit within the power supply compartment snugly or with very little space between the surface of the compartment and the battery, e.g., less than a millimeter between an external surface of the battery and a surface of the power supply compartment.

With respect to the battery, multiple batteries may be used. Further, the battery 404 may be rechargeable. The battery 404 may be coupled to the power input port 112a, the power output port 112b, the power knob 114 and a controller (not shown). The battery may be rechargeable. The case may include a DC-DC Converter. Input voltage can be 10-24v, allowing the case to be recharged, for example, from a 12v Cigarette lighter plug in a car via an AC wall adapter connection, DC cigarette plug from a vehicle, or from a solar panel. The power knob 114 may be coupled to the battery and/or controller to supply power to the controller and/or router without the need to remove the router from the case 100y7

There is no limitation on the type and size of battery. For example, two twelve volt 24 amp, LiFePo4 batteries may be used. The battery or batteries may be configured to provide power to the components within the case for as long as twenty-four hours non-stop, i.e., continuously during the twenty-four hour period.

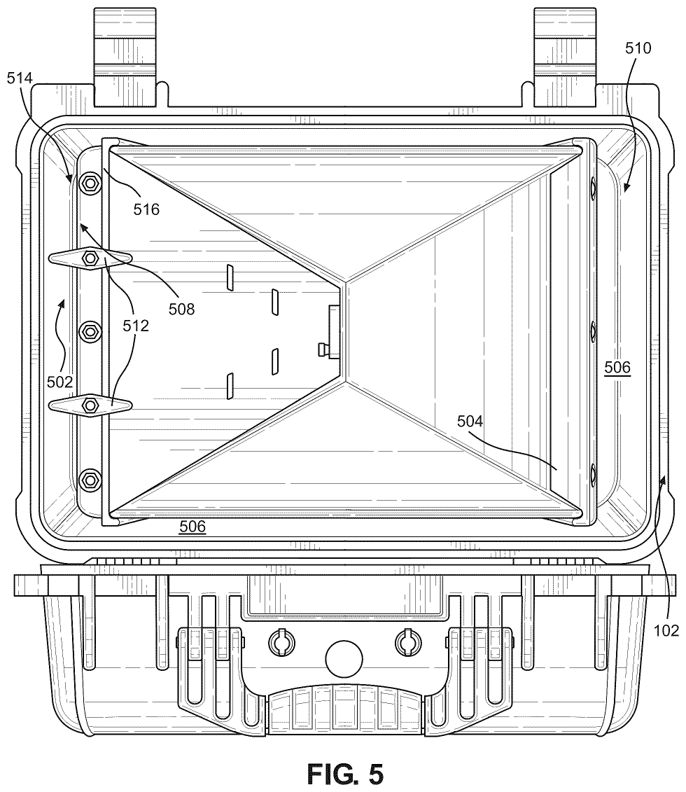

With reference to FIG. 5, the roof portion 102 may include a latch mount assembly 502 and a fixed mount 504. The latch mount assembly 502 and the fixed mount 504 may be on an interior surface 506 of the roof portion 102. The latch mount assembly 502 may be on a first side 508 of the interior surface 506 and the fixed mount may be on a second side 510 of the interior surface 506. The first side 508 and the second side 510 may be on opposing side regions of the roof portion 102.

The latch mount assembly 502 may include rotatable latches 512. The rotatable latches may be provided to lock a router in place against the interior surface 506 of the roof portion 102 and to allow removal of the router from the roof portion 102. For example, the rotatable latches 512 may be tabs that are rotatably fixed to a frame portion 514 of the latch mount assembly 502. The tabs may be able to rotate at least ninety degrees, but can also rotate three-hundred and sixty degrees. The rotatable latches 512 may be elongate and may extend equally to either side of an axis of rotation. The rotatable latches 512 may instead be configured to extend in only one direction from an axis of rotation. A detent such as a spring loaded bearing (not shown) may be provided to lock the rotatable latches in a position that secures a satellite router in place and may be provided to lock the rotatable latches in a position that allows removal of the satellite router from the case 100.

The latch mount assembly 502 may further include a positioning surface 516. The positioning surface 516 may be a surface against which a router rests when it is in the case 100. For example, the positioning surface 516 may be a bar as shown in FIG. 5; however, other types of geometries are possible such as a post, a plurality of posts, a knob or plurality of knobs, a mound, a ridge, etc.

The rotatable latches 512 and the positioning surface 516 may be a monolithic body with the frame portion 514. However, a monolithic character is not necessary as the rotating latches may be connected directly to the interior surface separately from the positioning surface, thereby eliminating the use of the frame portion 514.

Further, it is possible for the rotatable latch 512 to perform the function of the positioning surface 516, thereby eliminating the use of the positioning surface 516 altogether. For example, the rotatable latch 512 may include a pin at its axis of rotation. The pin may project from the rotatable latch 512 into a sleeve (not shown) that is integrally molded with the interior surface 506. The sleeve may serve the same function as the positioning surface in which a satellite router butts up against the posts in the interior surface 506.

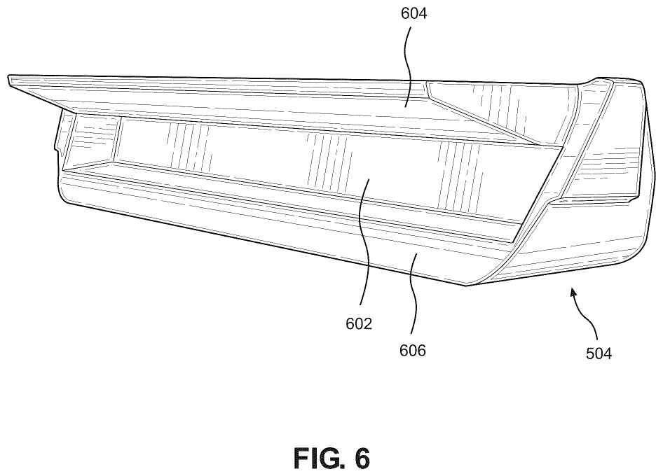

With reference to FIG. 6, the fixed mount 504 may be provided in the case to fix a satellite router in place in the roof portion 102. For example, a receiving slot 602 may be defined in the fixed mount 504. A satellite router may engage the receiving slot 602 and be partially encompassed thereby in that an edge of the satellite router would be nested within the receiving slot 602.

The fixed mount 504 may include an overhang 604. The overhang 604 may help to define the receiving slot 602. The overhang 604 helps to retain a satellite router in place regardless of the orientation of the case 100 and/or the roof portion 102. A fixed mount base 606 may be help define a portion of the receiving slot that opposes the overhang 604.

As shown in FIG. 6, the fixed mount base 606 may be shaped to correspond to a profile of the interior surface 506 of the roof portion 102. However, it is not necessary for the fixed mount base 606 to have a shape corresponding to the interior surface 506. Further, it is not necessary that a fixed mount base be present at all as the portion of the receiving slot 602 that opposes the overhang 604 may be defined by the interior surface 506. In such a situation, an overhang can be in the form of a flat plate attached to a side of the roof portion 102 so that it forms a “C” with the corner of the roof portion 102 or it can be an L-shaped bracket so that it forms a “C” with the interior surface.

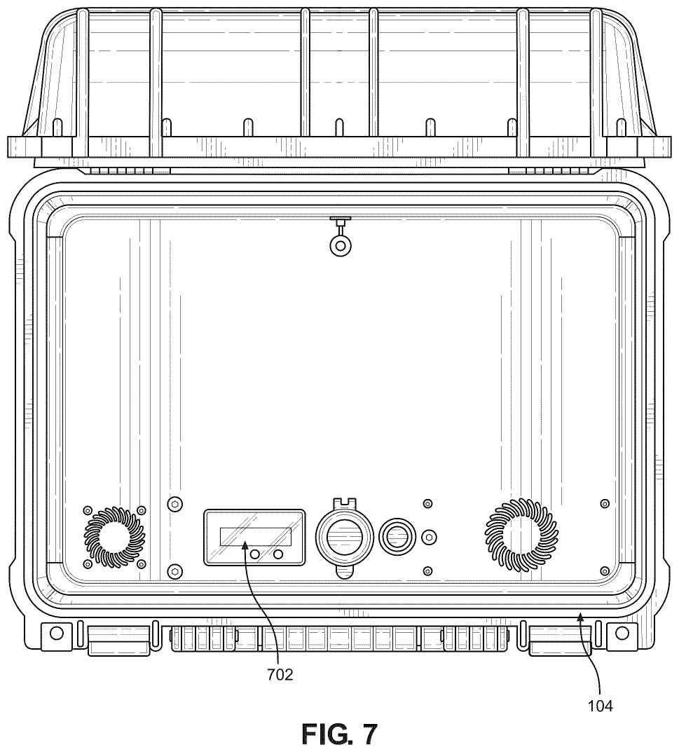

With reference to FIG. 7, various electronics may be included in the case 100. For example, a user interface and a controller may be included in the base portion 104. The user interface may be something as simple as a screen 702 to indicate a remaining power level of batteries in the case 100 and indicating a reception strength of the satellite router. In some embodiments, the user interface will be a touch screen that is configured to receive input to control operation of the electronics within the case 100. A visual battery power level indicator/gauge may be provided on an external portion of the case to provide an indication as to when recharging is required.

Other components may be included inside the case. For example, a 1500 watt DC-DC converter may be included inside the case. A cooling fan may be included to cool the batteries and/or the electronics within the case. One or more controllers and/or microcontrollers may be provided to control operation of the cooling fan, the battery and the router.

The satellite router may be connected to the controller and user interface via a hardwired connection or wirelessly. In some embodiments, it is possible to connect multiple satellite routers to the controller and user interface.

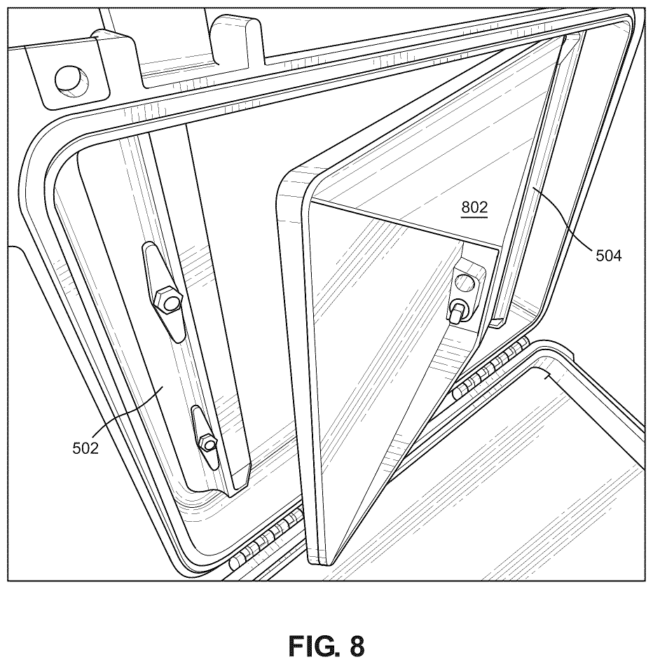

As noted above, the fixed mount 504 helps secure the satellite router on one side and allows for the router to rotate into the roof portion and drop into the latch mount assembly 502 on the other side of the roof portion. With reference to FIG. 8, to insert a router 802, an end of the router device slides into the fixed mount 504 at approximately 45 degrees relative to the roof of the case. The router 802 is then pivoted toward the roof portion of the case, the pivot point being the fixed mount 504. The overhang 604 of the fixed mount 504 is designed with at least a thirty-degree angle to allow approximately thirty degrees or more of rotational movement of the router 802 during insertion so that the opposite end of the router device can be inserted into the latch mount assembly 502 on the opposite side of the case lid. Each of the plurality of latches 208 are rotatable so that in the latched position, the hold the router device to the roof portion. Also, when the rotating latches 208 are in a latched position, they restrict freedom of movement of the router 802 relative to the fixed mount 504 and the roof portion 102. The latches 208 may be limited to ninety degrees of rotation by a diamond shaped post.

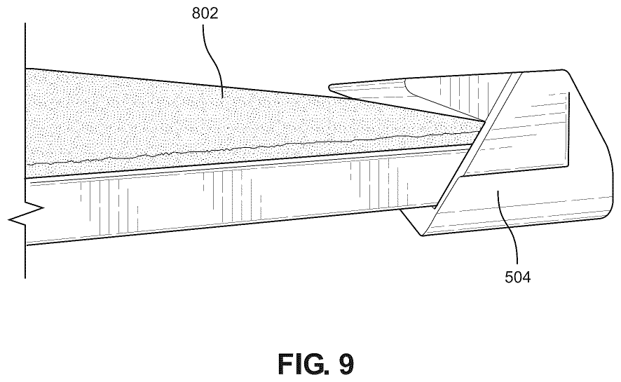

Once the router is in place in the upper portion 102, one or more of the plurality of rotating latches 208 may hold the router securely to the mount. The rotating latching mechanisms may have a spring detent plunger balls that keep the latches from auto rotating to the unlatched position to ensure the router does not fall out of mount. With reference to FIG. 9, the satellite router may be configured to intimately engage the fixed mount 504 in a nested configuration within the receiving slot 602 of the fixed mount 504.

The present embodiments of the disclosed case allow for the provision of powering a router and connected components externally, but they also provide a user the ability to open the case, turn the power on, then close the case with the router still mounted inside of the case. Once the case is closed and powered on, the case can be left out in the elements of weather without the risk of environmental effects like rain or snow damaging any of the power supply components or the router itself.

The discussion above is directed to certain specific embodiments. It is to be understood that the discussion above is only for the purpose of enabling a person with ordinary skill in the art to make and use any subject matter defined now or later by the patent “claims”found in any issued patent herein.

Applicant notes that some terms used herein have multiple definitions and/or multiple interpretations. For example, when an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

It is specifically intended that the claimed invention is not limited to the embodiments and illustrations contained herein but include modified forms of those embodiments including portions of the embodiments and combinations of elements of different embodiments as come within the scope of the following claims. It should be appreciated that in the development of any such actual embodiment, as in any engineering or design project, numerous embodiment-specific decisions may be made to achieve the developers'specific goals, such as compliance with system-related and business related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the claimed invention unless explicitly indicated as being “critical” or “essential.”

In the above detailed description, numerous specific details were set forth in order to provide a thorough understanding of the present disclosure. However, it will be apparent to one of ordinary skill in the art that the present disclosure may be practiced without these specific details. In other instances, well-known methods, procedures, components, circuits and networks have not been described in detail so as not to unnecessarily obscure aspects of the embodiment.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the invention. The first object or step, and the second object or step, are both objects or steps, respectively, but they are not to be considered the same object or step.

The terminology used in the description of the present disclosure herein is for the purpose of describing particular embodiments only and is not intended to be limiting of the present disclosure. As used in the description of the present disclosure and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components and/or groups thereof.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. As used herein, the terms “up” and “down”; “upper” and “lower”; “upwardly” and downwardly”; “below” and “above”; and other similar terms indicating relative positions above or below a given point or element may be used in connection with some embodiments of various technologies described herein.

Use of a quantitative term or value is not limited to the exact amount recited. For example, presence of the term “about” indicates an intention to convey that the same result can be achieved by using a value that is not exactly that recited. Similarly, if an objective can be achieved by using less than all of a specified amount, it may be so indicated through use of the term “substantial” or “substantially.” For example, fifty percent of a value may be considered substantial when the same result can be achieved as if 100% of a value is used. If an exact amount is required in order to achieve a result, it will have been specifically stated.

While the foregoing is directed to embodiments of various techniques described herein, other and further embodiments may be devised without departing from the basic scope thereof, which may be determined by the claims that follow. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A case for an internet receiving device comprising:
a roof portion;
a base portion connected to the roof portion;
a latch mount assembly on a first side of an interior surface of the roof portion, the latch mount assembly configured to at least partially secure the internet receiving device to the interior surface of the roof portion; and
a power supply partially encompassed by the base portion, the power supply configured to provide power to the internet receiving device.

2. The case as recited in claim 1, wherein the latch mount assembly comprises:
a rotating latch and a fixed mount, wherein the rotating latch is configured to rotate relative to the fixed mount.

3. The case as recited in claim 2, wherein the fixed mount is on a second side of the interior surface of the roof portion, the second side opposing the first side, the fixed mount being configured to at least partially secure the internet receiving device to the roof portion.

4. The case as recited in claim 2, wherein the latch mount assembly includes at least one second rotating latch.

5. The case as recited in claim 2, wherein a cross-section of the fixed mount includes a receiving slot and is adjacent a retaining overhang.

6. The case as recited in claim 1, further comprising:
a user interface assembly attached to and encompassed by the base portion.

7. The case as recited in claim 6, wherein the user interface assembly
a digital display;
at least one port coupled to the power supply and configured to supply power from the power supply to an external device and further configured to receive power for recharging the power supply; and
a controller configured to control operation of the battery and the digital display.

8. The case as recited in claim 7, wherein the user interface assembly is configured to electronically couple to an internet receiving device.

9. The case as recited in claim 7, further comprising:
an accessory output port configured to relay signals from a satellite to a connected accessory.

10. The case as recited in claim 7, wherein the positioning surface may be a form selected from the group consisting of: a bar, a pin, a rail and a ridge.

11. A case comprising:
a roof portion;
a base portion connected to the roof portion;
a latch mount assembly on a first side of an interior surface of the roof portion, the latch mount assembly;
an internet receiving device at least partially secured to the interior surface of the roof portion; and
a power supply partially encompassed by the base portion, the power supply configured to provide power to the internet receiving device.

12. The case as recited in claim 11, wherein the latch mount assembly comprises:
a rotating latch and a fixed mount, wherein the rotating latch is configured to rotate relative to the fixed mount.

13. The case as recited in claim 12, wherein the fixed mount is on a second side of the interior surface of the roof portion, the second side opposing the first side, the fixed mount being configured to at least partially secure the internet receiving device to the roof portion.

14. The case as recited in claim 12, wherein the latch mount assembly includes at least one second rotating latch.

15. The case as recited in claim 12, wherein a cross-section of the fixed mount includes a receiving slot and is adjacent a retaining overhang.

16. The case as recited in claim 11, further comprising:
a user interface assembly attached to and encompassed by the base portion.

17. The case as recited in claim 16, wherein the user interface assembly includes,
the power supply;
a positioning surface;
a digital display;
at least one port coupled to the power supply and configured to supply power from the power supply to an external device and further configured to receive power for recharging the power supply; and
a controller configured to control operation of the battery and the digital display.

18. The case as recited in claim 17, wherein the user interface assembly is configured electronically coupled to the internet receiving device.

19. The case as recited in claim 17, further comprising:
an accessory output port configured to relay signals from a satellite to a connected accessory.

20. The case as recited in claim 17, wherein the positioning surface may be a form selected from the group consisting of: a bar, a pin, a rail and a ridge.
